(19) United States
(12) Patent Application Publication
(10) Pub. No.: US 2026/0059887 A1
(43) Pub. Date: Feb. 26, 2026

(54) PIXEL AND IMAGE SENSOR INCLUDING THE SAME

(71) Applicant: Samsung Electronics Co., Ltd., Suwon-si (KR)

(72) Inventor: Junho SEOK, Suwon-si (KR)

(73) Assignee: Samsung Electronics Co., Ltd., Suwon-si (KR)

(21) Appl. No.: 19/240,660

(22) Filed: Jun. 17, 2025

(30) Foreign Application Priority Data
Aug. 26, 2024 (KR) 10-2024-0114414

(51) Int. Cl. H10F 39/00; H04N 25/77

(52) U.S. Cl. CPC H10F 39/811; H04N 25/77; H10F 39/807

(57) ABSTRACT

A pixel of an image sensor includes a first sub-pixel, a second sub-pixel, a floating diffusion region, a gate insulating layer, a source follower gate and a contact. The first sub-pixel includes a first photoelectric conversion element in a semiconductor substrate. The second sub-pixel includes a second photoelectric conversion element in the semiconductor substrate. The floating diffusion region is in the semiconductor substrate and shared by the first sub-pixel and the second sub-pixel. The gate insulating layer is above the semiconductor substrate. The source follower gate is above the gate insulating layer. The contact connects the floating diffusion region and the source follower gate not via a metal line in a metal layer.

### CROSS-REFERENCE TO RELATED APPLICATION

This U.S. non-provisional application claims priority under 35 USC § 119 to Korean Patent Application No. 10-2024-0114414, filed on Aug. 26, 2024, in the Korean Intellectual Property Office (KIPO), the contents of which is incorporated by reference herein in its entirety.

### BACKGROUND

Some example embodiments relate generally to semiconductor integrated circuits, and more particularly to a pixel and an image sensor including the pixel.

Complementary metal oxide semiconductor (CMOS) image sensors are or include solid-state sensing devices that use complementary metal oxide semiconductors. CMOS image sensors have lower manufacturing costs and/or lower power consumption compared with charge-coupled device (CCD) image sensors. Thus CMOS image sensors are used for various electronic appliances including portable devices such as, for example, smartphones and/or digital cameras.

A pixel array included in a CMOS image sensor may include a photoelectric conversion element such as a photodiode in each pixel. The photoelectric conversion element generates an electrical signal that varies based on the quantity of incident light. The CMOS image sensor processes electrical signals to synthesize an image. With the recent proliferation of high-resolution images, pixels included in the CMOS image sensor are becoming much smaller. When the pixels get smaller, incident light may not be properly sensed and/or noise may occur due to interference between highly integrated elements. Alternatively or additionally, the CMOS image sensor is expected to have enhanced image quality and to perform additional functions such as auto focusing.

### SUMMARY

Some example embodiments may provide a pixel having enhanced electrical characteristics, and an image sensor including the pixel.

According to some example embodiments, a pixel of an image sensor includes a first sub-pixel, a second sub-pixel, a floating diffusion region, a gate insulating layer, a source follower gate and a contact. The first sub-pixel includes a first photoelectric conversion element in a semiconductor substrate. The second sub-pixel includes a second photoelectric conversion element in the semiconductor substrate. The floating diffusion region is in the semiconductor substrate and shared by the first sub-pixel and the second sub-pixel. The gate insulating layer is above the semiconductor substrate. The source follower gate is above the gate insulating layer. The contact connects, the floating diffusion region and the source follower gate not via a metal line in a metal layer.

Alternatively or additionally according to some example embodiments, an image sensor includes a pixel array including a plurality of pixels configured to collect photo charges generated by an incident light, a row driver configured to drive the pixel array row by row, and a controller configured to control the pixel array and the row driver. Each pixel of the plurality of pixels includes a first sub-pixel including a first photoelectric conversion element in a semiconductor substrate, a second sub-pixel including a second photoelectric conversion element in the semiconductor substrate, a floating diffusion region in the semiconductor substrate and shared by the first sub-pixel and the second sub-pixel, a gate insulating layer above the semiconductor substrate, a source follower gate above the gate insulating layer, and a contact connecting the floating diffusion region and the source follower gate not via a metal line in a metal layer.

Alternatively or additionally according to some example embodiments, a pixel of an image sensor includes a first sub-pixel, a second sub-pixel, a microlens shared by the first sub-pixel and the second sub-pixel, a floating diffusion region in a semiconductor substrate and shared by the first sub-pixel and the second sub-pixel, a gate insulating layer above the semiconductor substrate, a source follower gate disposed above the gate insulating layer, and a contact connecting the floating diffusion region and the source follower gate not via a metal line in a metal layer.

The pixel and the image sensor according to some example embodiments may reduce the capacitance of the floating diffusion region and the source follower gate and increase the conversion gain of the pixel, by connecting the floating diffusion region and the source follower gate using the contact.

Alternatively or additionally, the pixel and the image sensor according to some example embodiments may reduce the amount of metal consumed in the manufacturing process to reduce manufacturing costs by replacing the metal lines above the pixel with the contact, and to improve the electrical characteristics of the pixel and the image sensor by reducing interference between metal lines.

### BRIEF DESCRIPTION OF THE DRAWINGS

Some example embodiments will be more clearly understood from the following detailed description taken in conjunction with the accompanying drawings.

FIG. 1 is a plan view illustrating a layout of a pixel included in an image sensor according to some example embodiments.

FIGS. 2A through 5 are cross-sectional views illustrating example embodiments of a vertical structure of a pixel included in an image sensor according to some example embodiments.

FIG. 6 is a circuit diagram illustrating a configuration corresponding to the pixel of FIG. 1 and a readout circuit.

FIGS. 7 and 8 are cross-sectional views illustrating example embodiments of a direct contact included in a pixel according to some example embodiments.

FIG. 9 is a block diagram illustrating an image sensor according to some example embodiments.

FIG. 10 is a circuit diagram illustrating an example of a unit circuit included in an image sensor according to some example embodiments.

FIG. 11 is a timing diagram illustrating an example operation of an image sensor according to some example embodiments.

FIG. 12 is a diagram illustrating a stack structure of an image sensor according to some example embodiments.

FIG. 13 is a cross-sectional view illustrating an example embodiment in which a direct contact is applied to a pixels included in an image sensor of a stack structure according to some example embodiments.

FIGS. 14 and 15 are plan views illustrating a layout of a pixel group included in an image sensor according to some example embodiments.

FIG. 16 is a circuit diagram illustrating a configuration corresponding to the pixel group of FIGS. 14 and 15 and a readout circuit.

FIG. 17 is a plan view illustrating a layout of a pixel group included in an image sensor according to some example embodiments.

FIG. 18 is a circuit diagram illustrating a configuration corresponding to the pixel group of FIG. 17 and a readout circuit.

FIG. 19 is a diagram illustrating a layout of a pixel array included in an image sensor according to some example embodiments.

FIGS. 20 through 24 are plan views illustrating example embodiments of an arrangement pattern of a pixel array included in an image sensor according to some example embodiments.

FIG. 25 is a block diagram illustrating an electronic device according to some example embodiments.

FIG. 26 is a block diagram illustrating a camera module included in the electronic device of FIG. 25.

### DETAILED DESCRIPTION OF SOME EXAMPLE EMBODIMENTS

Various example embodiments will be described more fully hereinafter with reference to the accompanying drawings, in which some example embodiments are shown. In the drawings, like numerals refer to like elements throughout. The repeated descriptions may be omitted.

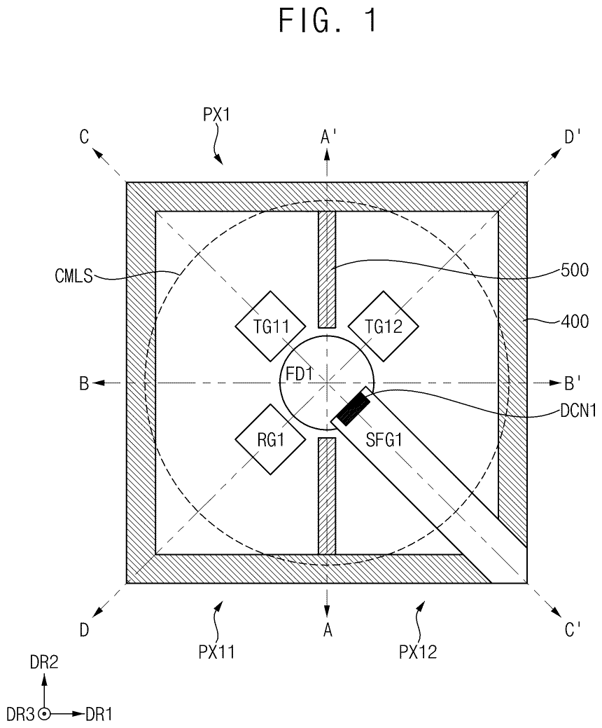

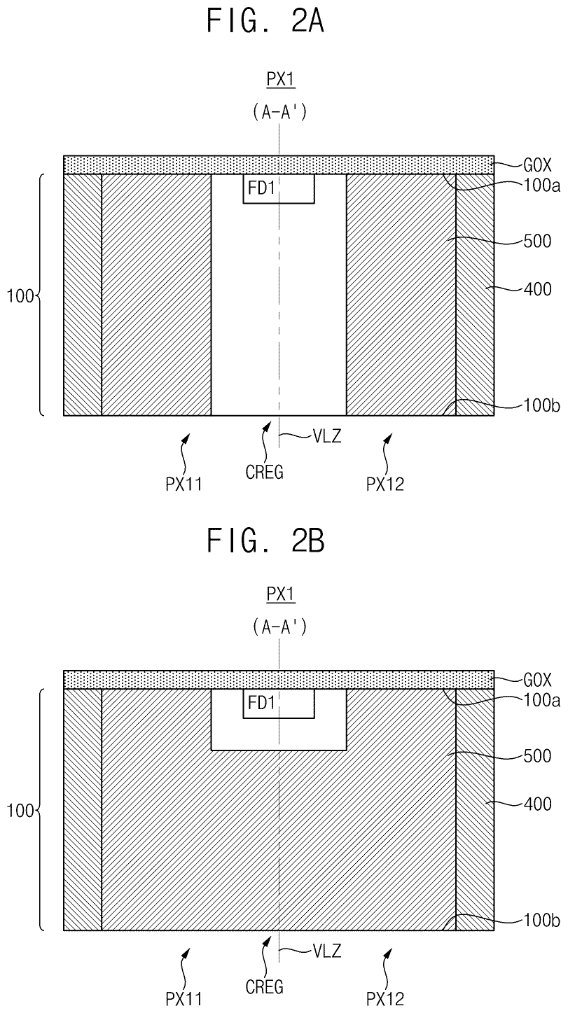

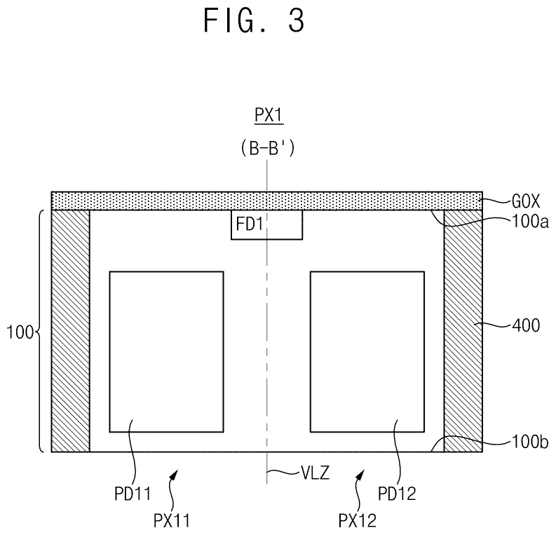

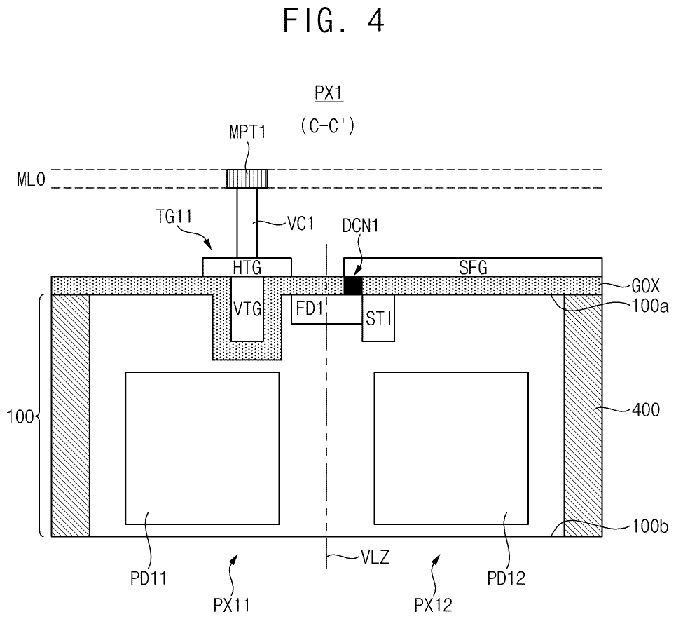

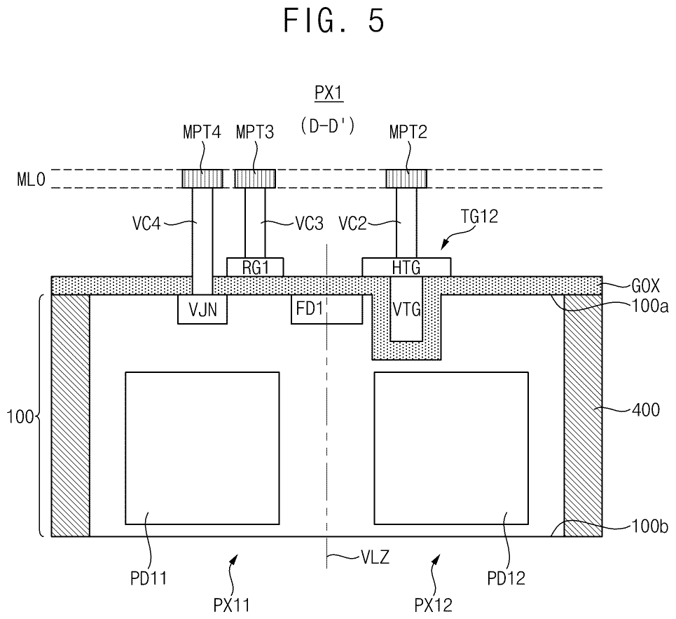

FIG. 1 is a plan view illustrating a layout of a pixel included in an image sensor according to some example embodiments, and FIGS. 2A through 5 are cross-sectional views illustrating example embodiments of a vertical structure of a pixel included in an image sensor according to some example embodiments. FIGS. 2A and 2B are a cross-sectional views cut along the A-A′ line of FIG. 1, FIG. 3 is a cross-sectional view cut along the B-B′ line of FIG. 1, FIG. 4 is a cross-sectional view cut along the C-C′ line of FIG. 1, and FIG. 5 is a cross-sectional view cut along the D-D′ line of FIG. 1.

Hereinafter, two directions parallel to and intersecting the upper and lower surfaces of the semiconductor substrate may be defined as a first horizontal direction DR1 and a second horizontal direction DR2, respectively, and a direction substantially perpendicular to the upper and bottom surfaces of the semiconductor substrate may be defined as a vertical direction DR3. The first horizontal direction DR1 may correspond to a row or word line direction and the second horizontal direction DR2 may correspond to a column or bit line direction.

Referring to FIGS. 1 through 5, a pixel PX1 may include a first sub-pixel PX11, a second pixel PX12, a floating diffusion node or floating diffusion region FD1, a source follower gate SFG1 and a contact, e.g., a direct contact DCN1.

The first sub-pixel PX11 may include a first photoelectric conversion element PD11 disposed in or at least partially in a semiconductor substrate 100 and a first transfer gate TG11 disposed above or at least partially above the semiconductor substrate 100.

The second sub-pixel PX12 may include a second photoelectric conversion element PD12 disposed in the semiconductor substrate 100 and a second transfer gate TG12 disposed above the semiconductor substrate 100.

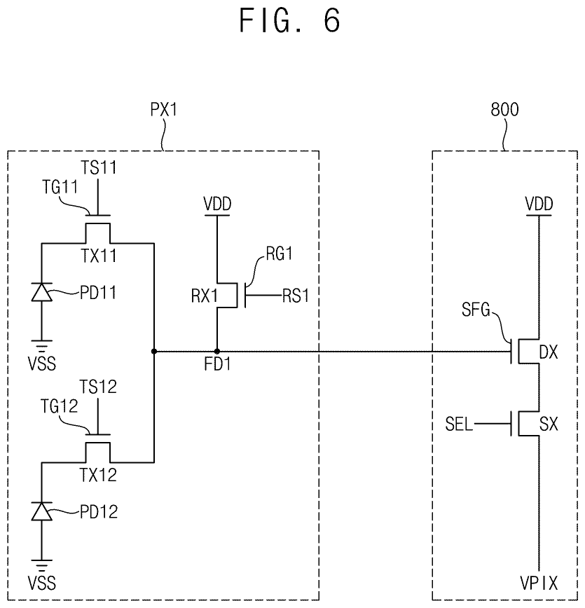

In some example embodiments, the first sub-pixel PX11 may further include a reset gate RG1 disposed above the semiconductor substrate 100. The reset gate RG1 may be considered a portion of the pixel, or may be considered a portion of the readout circuit as will be described below with reference to FIG. 6; example embodiments are not limited thereto.

The floating diffusion region FD1 may be disposed in the semiconductor substrate 100 and shared by the first sub-pixel PX11 and the second sub-pixel PX12. In some example embodiments, the floating diffusion region FD1 may be disposed in the center portion of the pixel PX1.

The gate isolation layer GOX may be disposed above the semiconductor substrate 100.

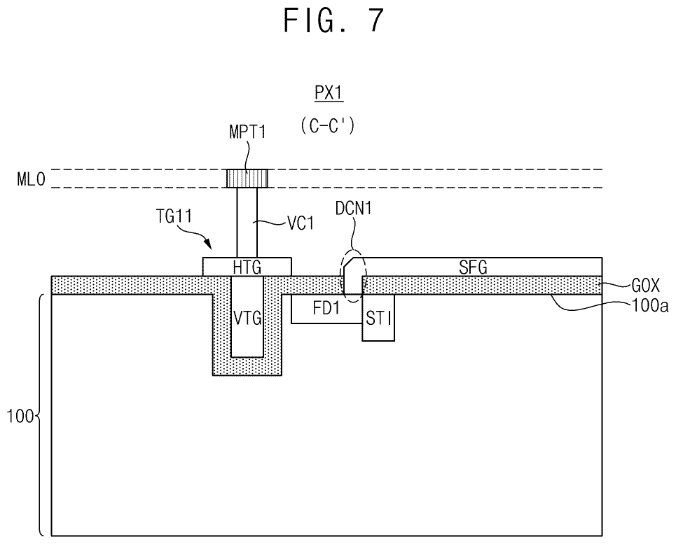

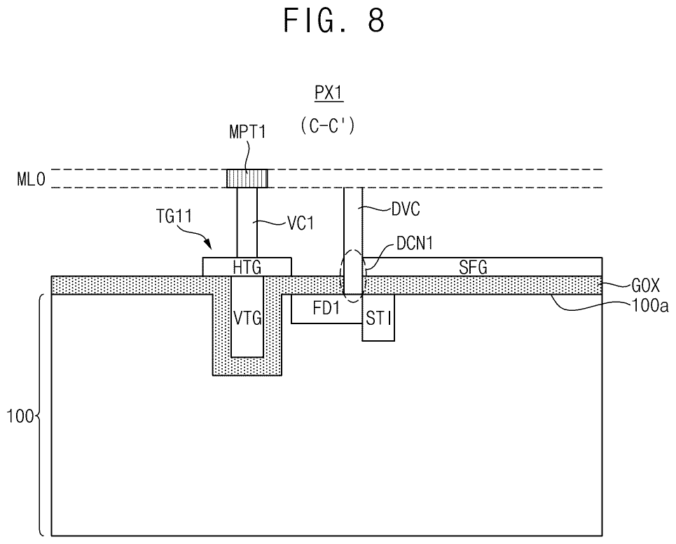

The source follower gate SFG1 may be disposed above the gate insulating layer GOX and may be connected to the floating diffusion region FD1 via the direct contact DCN1; the direct contact may not include or be connected to or be directly connected to a metal line of a metal layer and/or a poly line of a poly layer above the semiconductor substrate 100. The source follower gate SFG1 may be considered as a portion of the pixel, or may be considered as a portion of the readout circuit; example embodiments are not limited thereto. Example embodiments of the direct contact DCN1 will be further described with reference to FIGS. 7 and 8.

The trench structures 400 and 500 may be disposed in the interior of the semiconductor substrate 100 extending in a vertical direction DR3 from an upper surface 100a to a bottom surface 100b of the semiconductor substrate 100, and may electrically and optically isolate the photoelectric conversion elements PD11 and PD12 respectively included in the first subpixel PX11 and the second subpixel PX12. In some example embodiments, each of or at least one of the photoelectric conversion elements PD11 and PD12 may be or may include photodiodes; example embodiments are not limited thereto. The trench structures 400 and 500 may include an inter-pixel trench structure 400 that isolates each pixel PX1 and neighboring pixels, and an intra-pixel trench structure 500 that isolates the first sub-pixel PX11 and second sub-pixel PX12 included in each pixel PX1 from each other.

The inter-pixel trench structures 400 may extend in a vertical direction DR3 from the upper surface 100a to the lower or bottom surface 100b of the semiconductor substrate 100, and may surround the periphery of the first sub-pixel PX11 and the second sub-pixel PX12.

The intra-pixel trench structure 500 may prevent or reduce the amount of and/or occurrence of and/or impact from incident light incident on each of the first photoelectric conversion element PD11 and the second photoelectric conversion element PD12 and photo charges generated by the incident light from being transferred to the other neighboring sub-pixel. For example, the intra-pixel trench structure 500 may prevent or reduce crosstalk between the photoelectric conversion elements PD11 and PD12. Alternatively or additionally, the inter-pixel trench structure 400 may prevent or reduce crosstalk between each pixel PX1 and neighboring pixels.

In some example embodiments, as shown in FIG. 2A, a portion corresponding to the center region CREG on a center vertical line VLZ of the intra-pixel trench structure 500 may be removed in a vertical direction DR3 from the upper surface 100a to the bottom surface 100b of the semiconductor substrate 100.

In some example embodiments, as shown in FIG. 2B, a portion corresponding to the center region CREG on the center vertical line VLZ of the intra-pixel trench structure 500 may only be partially removed starting from the upper surface 100a of the semiconductor substrate 100. The floating diffusion region FD1 may be disposed in the center region CREG from which the intra-pixel trench structure 500 is removed. The central region CREG allows electrons to pass between sub-pixels, which may be controlled by the potential profile formed on the semiconductor substrate 100 depending on the removed length and the fabrication process.

In some example embodiments, as shown in FIGS. 4 and 5, each of the first transfer gate TG11 and the second transfer gate TG12 may be implemented as a combination of a horizontal transfer gate HTG and a vertical transfer gate VTG. The vertical transfer gate VTG may be surrounded by the gate isolation layer GOX. In some example embodiments, each of the first transfer gate TG11 and the second transfer gate TG12 may include only the horizontal transfer gate HTG or only the vertical transfer gate VTG.

In some example embodiments, as shown in FIGS. 3, 4, and 5, the semiconductor substrate 100 may have the first photodiode PD11 and the second photodiode PD12 formed in the first subpixel PX11 and the second subpixel PX12, respectively. For example, if the semiconductor substrate 100 is a P-type conductive type, the photodiodes PD11 and PD12 may be or may include an N-type conductive type.

According to some example embodiments, the semiconductor substrate 100 includes a plurality of regions that are distinguished by being doped with different concentrations of impurities and/or different conductivity types. For example, if the semiconductor substrate 100 is a P-type conductive type, the semiconductor substrate may include a background P-type dopants such as boron incorporated therein. A concentration of background P-type dopants may be relatively small. The semiconductor substrate 100 may include, sequentially from top to bottom, an N− region, a P− region, and a P+ region. The P− region indicates that it is doped with impurities of the opposite conductivity to the N− region, and the P+ region indicates that it has a higher concentration of impurities than the P− region. The incident photons penetrate into the P− region and generate electron-hole pairs, e.g., the P− region may correspond to the dominant photocurrent generation region. The resulting photoelectrons as minority carriers may migrate to the depletion region of the N-P conjunction, which corresponds to the boundary between the N− and P− regions. In this case, the photoelectrons generated near the boundary between the P− and P+ regions are more inclined to migrate to the N-P conjunction portion due to the presence of a P+ region, with a larger concentration of impurities downstream of the P− region. In some example embodiments, the N− region may be replaced by a P region and/or a P− region. In some example embodiments, a P− region, a P region, and/or a P+ region may include dopants such as boron; in some example embodiments, an N− region, an N region, and/or an N+ region may include dopants such as arsenic and/or phosphorus. Example embodiments are not limited thereto.

As shown in FIG. 1, the first sub-pixel PX11 and the second sub-pixel PX12 may share one microlens CMLS, and the pixel PX1 may be or may include a two-photodiode (2PD) pixel for autofocusing.

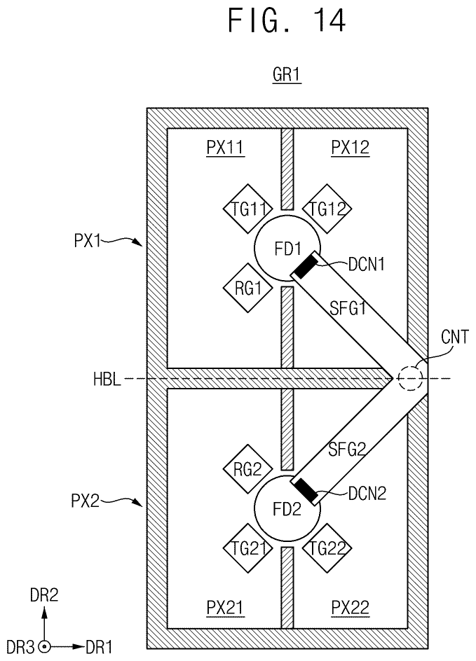

As shown in FIG. 1, the source follower gate SFG1 may extend from the floating diffusion region FD1 to one corner region of the square shape of the pixel PX1. As will be described below with reference to FIGS. 14 through 18, the source follower gate SFG1 extended to the corner region may be utilized to efficiently integrate the source follower gates of a plurality of pixels.

As shown in FIGS. 4 and 5, the signalized gates TG11, TG12 and RG1 and the voltage applied junction regions VJN may be connected to metal lines MPT1 to MPT4 formed in a metal layer ML0, via vertical contacts VC1 through VC4.

FIG. 6 is a circuit diagram illustrating a configuration corresponding to the pixel of FIG. 1 and a readout circuit. Hereinafter, descriptions that are redundant with FIGS. 1 through 5 may be omitted.

Referring to FIG. 6, a pixel PX1 may include a floating diffusion region FD1, a first photodiode PD11 and a first transfer transistor TX11 in a first sub-pixel PX11, a second photodiode PD12 and a second transfer transistor TX12 in a second sub-pixel PX12, and a reset transistor RX1. The first sub-pixel PX11, the second sub-pixel PX12 and the reset transistor RX1 are connected in common to the floating diffusion region FD1.

Electrical and/or physical characteristics of each of the first transfer transistor TX11, the second transfer transistor TX12, and the reset transistor RX1 may be the same, or at least one electrical property and/or at least one physical property of at least one of the first transfer transistor TX11, the second transfer transistor TX12, and the reset transistor RX1 may be different than at least another of the first transfer transistor TX11, the second transfer transistor TX12, and the reset transistor RX1. Example embodiments are not limited thereto.

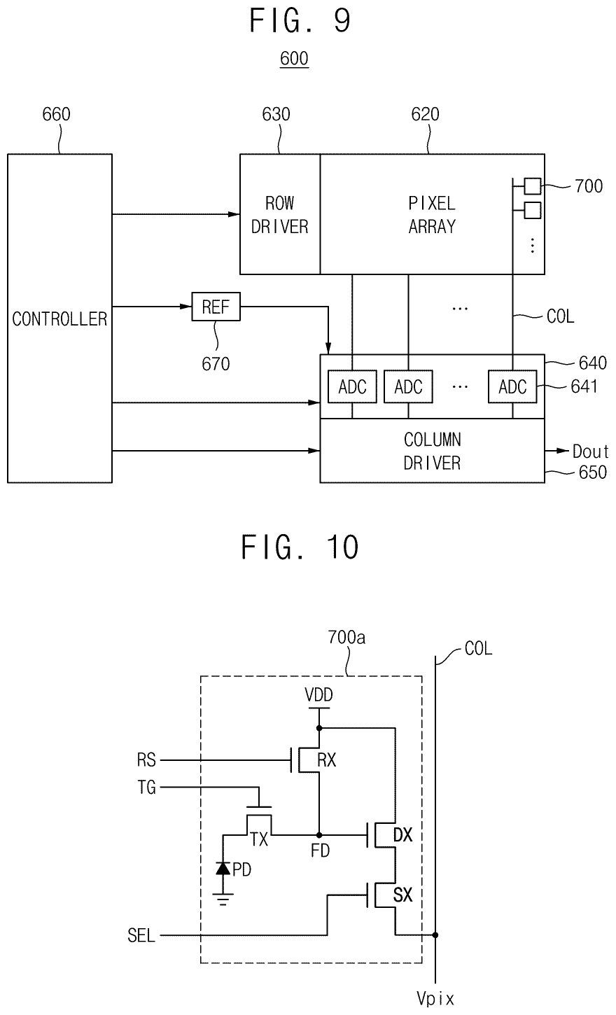

Control signals TS11, TS12 and RS1 provided to the gates TG11, TG12 and RG1 of the pixel PX1 may be transmitted from a row drive 630 of FIG. 9 via wiring in the row direction, i.e., the first horizontal direction DR1.

A readout circuit 800 may include a source follower transistor or drive transistor DX and a selection transistor SX. While FIG. 6 illustrates a structure in which each sub-pixel includes one transistor and the readout circuit includes two transistors for convenience of illustration and description, it will be understood that example embodiments may be adapted to a variety of other configurations.

The reset transistor RX1 may be connected between the floating diffusion region FD1 and a reset voltage, such as a supply voltage VDD. The reset transistor RX1 may be switched in response to a reset signal RS1 applied to the reset gate RG1.

For illustrative purposes, only the gate of the drive transistor DX, e.g., the source follower gate SFG1, is shown in FIGS. 1 through 5 and the gate of the selection transistor SX is omitted. The selection transistor SX may be disposed at any suitable location in the boundary region between pixels or in the interior of a pixel.

FIGS. 7 and 8 are cross-sectional views illustrating example embodiments of a direct contact included in a pixel according to some example embodiments. Hereinafter, descriptions that are redundant with FIGS. 1 through 5 may be omitted.

Referring to FIG. 7, according to some example embodiments, a portion of the gate insulating layer above the floating diffusion region FD1 may be removed, and the direct contact DCN1 may include a conductive material that fills the removed portion to connect the floating diffusion region FD1 and the source follower gate SFG.

A conductive material of the direct contact DCN1 may be the same as a conductive material of the source follower gate SFG1. In some example embodiments, the conductive material of the direct contact DCN1 may include polysilicon such as undoped or doped polysilicon. In some example embodiments, the conductive material of the direct contact DCN1 may include a barrier metal (BM).

The direct contact DCN1 of FIG. 7 may be formed by performing an etching process, such as a wet and/or dry etching process, to remove the portion of the gate insulating layer GOX above the floating diffusion region FD1, followed by a deposition process, such as a chemical and/or physical deposition process, to form the source follower gate SFG1 to include the removed portion of the gate insulating layer GOX.

The transfer gate TG11 may be connected to the metal line MPT1 of the metal layer ML0 via a vertical contact VC1.

Referring to FIG. 8, the direct contact DCN1 may include a vertical contact DVC extending in a vertical direction DR3 from the upper surface of the floating diffusion region FD1 to the metal layer ML0, and having a sidewall in contact with an end portion of the source follower gate FD1. The vertical contact DVC corresponds to a dummy vertical contact that is floating and not connected to the metal lines of the metal layer ML0.

The direct contact DCN1 of FIG. 8 may be formed by performing a deposition process, such as a physical and/or chemical deposition process, to form the source follower gate SFG1 to overlap in a vertical direction DR3 with the end portion of the floating diffusion region FD1, performing an etching process, such as a wet and/or dry etching process, to remove a portion of the gate insulating layer GOX where the floating diffusion region FD1 and the source follower gate SFG1 overlap in the vertical direction DR3, and performing a filling process, such as a chemical and/or physical filling process, to form a vertical contact DVC in the overlapping portion.

As such, the pixel and the image sensor according to some example embodiments may reduce the capacitance of the floating diffusion region and the source follower gate and/or increase the conversion gain of the pixel, by connecting the floating diffusion region and the source follower gate using the direct contact, e.g., by directly connecting the floating diffusion region and the source follower gate.

Alternatively or additionally, the pixel and the image sensor according to some example embodiments may reduce the amount of metal consumed in the manufacturing process to reduce manufacturing costs by replacing the metal lines above the pixel with the direct contact, and improve the electrical characteristics of the pixel and the image sensor by reducing interference between metal lines.

FIG. 9 is a block diagram illustrating an image sensor according to some example embodiments.

Referring to FIG. 9, an image sensor 600 may include a pixel array 620, a row driver 630, an analog-to-digital conversion circuit 640, a column driver 650, a controller 660, and/or a reference signal generator REF 670.

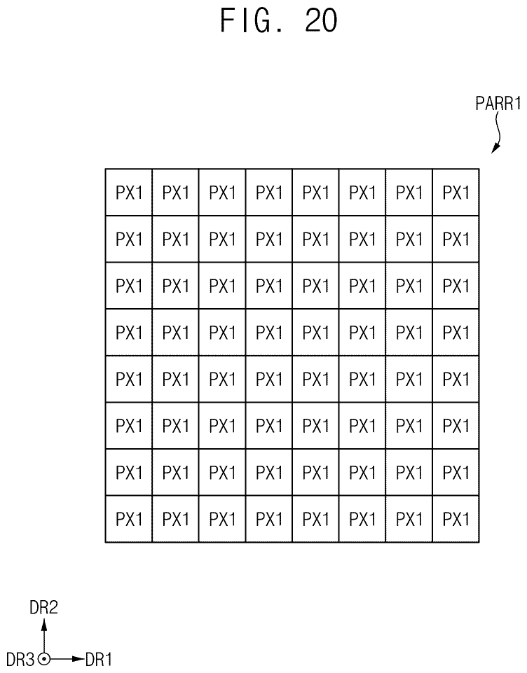

The pixel array 620 includes a plurality of pixels 700 coupled to column lines COL, respectively, and the plurality of pixels 700 senses incident light to generate analog signals through the column lines COL. The plurality of pixels 700 may be arranged in matrix form, e.g., in a rectangular or square form, with a plurality of rows and a plurality of columns. The pixel array 620 may have a structure that various unit patterns, which will be described below with reference to FIGS. 19 through 24, are arranged repeatedly in the first horizontal direction DR1 and the second horizontal direction DR2.

The row driver 630 may be coupled to the rows of the pixel array 620 to generate signals for driving the rows. For example, the row driver 630 may drive the pixels in the pixel array 620 row by row.

The analog-to-digital conversion circuit 640 may be coupled to the columns of the pixel array 620 to convert the analog signals from the pixel array 20 to digital signals. As illustrated in FIG. 9, the analog-to-digital conversion circuit 640 may include a plurality of analog-to-digital converters (ADC) 641 to perform analog-to-digital conversion of the analog signals output from the column lines COL in parallel or simultaneously.

The analog-to-digital conversion circuit 640 may include a correlated double sampling (CDS) unit. In some example embodiments, the CDS unit may perform an analog double sampling by extracting a valid image component based on a difference between an analog reset signal and an analog image signal. Alternatively or additionally, in some example embodiments, the CDS unit may perform a digital double sampling by converting the analog reset signal and the analog image signal to two digital signals and extracting a difference between the two digital signals as the valid image component. Alternatively or additionally, in some example embodiments, the CDS unit may perform a dual CDS by performing both the analog double sampling and digital double sampling.

The column driver 650 may output the digital signals from the analog-to-digital conversion circuit 40 sequentially as output data Dout.

The controller 660 may control the row driver 30, the analog-to-digital conversion circuit 640, the column driver 650, and/or the reference signal generator 670. The controller 660 may provide control signals such as clock signals, timing control signals, etc. required for the operations of the row driver 630, the analog-to-digital conversion circuit 640, the column driver 650, and/or the reference signal generator 670. The controller 660 may include one or more of a control logic circuit, a phase-locked loop, a timing control circuit, a communication interface circuit, etc.

The reference signal generator 670 may generate a reference signal or a ramp signal that increases or decreases gradually and provide the ramp signal to the analog-to-digital conversion circuit 40.

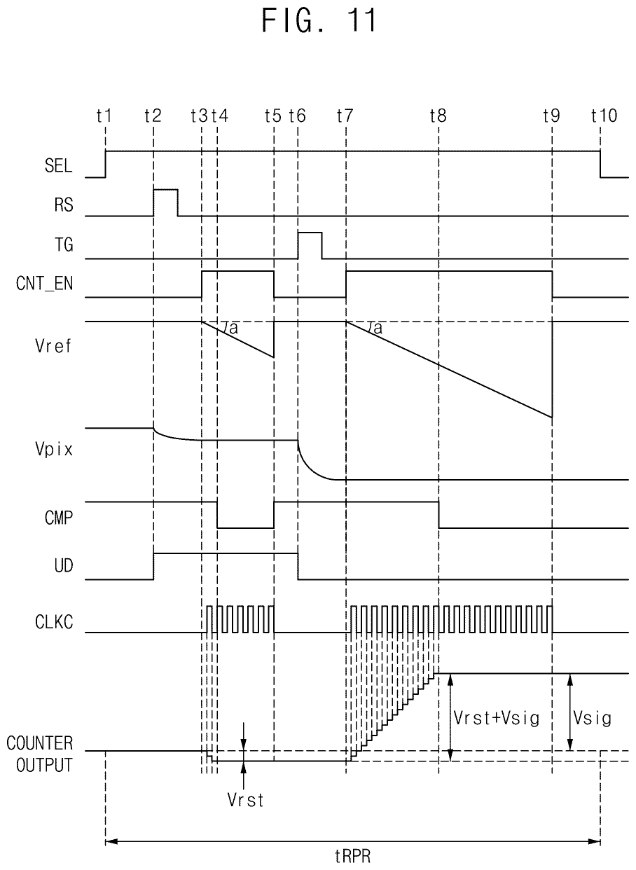

FIG. 10 is a circuit diagram illustrating an example of a unit circuit included in an image sensor according to some example embodiments.

Referring to FIG. 10, a unit pixel 700a may include a photo-sensitive element such as a photodiode PD, and a readout circuit including a transfer transistor TX, a reset transistor RX, a drive transistor DX and/or a selection transistor SX.

For example, the photodiode PD may include an n-type region in a p-type substrate such that the n-type region and the p-type substrate form a p-n conjunction diode. The photodiode PD receives the incident light and generates a photo-charge based on the incident light. In some example embodiments, the unit pixel 600a may include a phototransistor, a photogate, and/or a pinned photodiode, etc. instead of, or in addition to, the photodiode PD.

The photo-charge generated in the photodiode PD may be transferred to a floating diffusion node FD through the transfer transistor TX. The transfer transistor TX may be turned on in response to a transfer control signal TG.

The drive transistor DX may function as a source follower amplifier that amplifies a signal corresponding to the charge on the floating diffusion node FD. The selection transistor SX may transfer the pixel signal Vpix to a column line COL in response to a selection signal SEL.

The floating diffusion node FD may be reset by the reset transistor RX. For example, the reset transistor RX may discharge the floating diffusion node FD in response to a reset signal RS for correlated double sampling (CDS).

FIG. 10 illustrates the unit pixel 700a of the four-transistor configuration including the four transistors TX, RX, DX and SX. The configuration of the unit pixel may be variously changed and the pixel structure is not limited to that of FIG. 10.

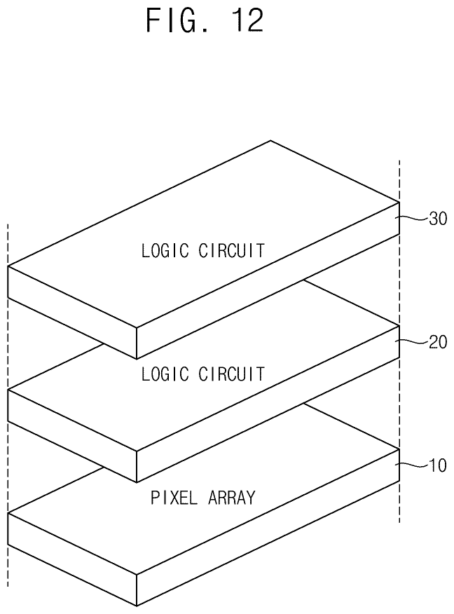

FIG. 11 is a timing diagram illustrating an example operation of an image sensor according to some example embodiments.

FIG. 11 illustrates a sensing period tRPR corresponding to a sensing operation of a pixel. The sensing operation may be performed simultaneously with respect to pixels corresponding to the same transfer control signal TG.

Referring to FIGS. 9, 10 and 11, at a time t1, the row driver 630 may select one of rows included in the pixel array 20 by providing an activated row selection signal SEL to the selected row of the pixel array 620.

At a time t2, the row driver 630 may provide an activated reset control signal RS to the selected row, and the controller 60 may provide an up-down control signal UD having a logic high level to a counter included in the ADC 641. From the time t2, the pixel array 620 may output a first analog signal corresponding to a reset component Vrst as the pixel voltage Vpix.

At a time t3, the controller 660 may provide a count enable signal CNT_EN having a logic high level to the reference signal generator 670, and the reference signal generator 670 may start to decrease the reference signal Vref at the constant rate, e.g., a slope of ‘a’. The controller 660 may provide a count clock signal CLKC to the counter, and the counters may perform down-counting from zero in synchronization with the count clock signal CLKC.

At a time t4, a magnitude of the reference signal Vref may become smaller than a magnitude of the pixel voltage Vpix, and a comparator included in the ADC 641 may provide a comparison signal CMP having a logic low level to the counter so that the counter stops performing the down-counting. At the time t4, a counter output of the counter may be the first counting value that corresponds to the reset component Vrst. In the example of FIG. 11, the counter output of the counter at the time t4 may be −2.

At a time t5, the controller 660 may provide the count enable signal CNT_EN having a logic low level to the reference signal generator 670, and the reference signal generator 670 may stop generating the reference signal Vref.

A period from the time t3 to the time t5 corresponds to a maximum time for detecting the reset component Vrst. A length of the period from the time t3 to the time t5 may be determined as a certain number of the count clock signal CLKC according to a characteristic of the image sensor 700.

At a time t6, the row driver 630 may provide an activated transfer control signal TG (e.g., the transfer control signal TG having a logic high level) to the selected row, and the controller 660 may provide the up-down control signal UD having a logic low level to the counter. From the time t6, the pixel array 620 may output a second analog signal AS2 corresponding to a detected incident light Vrst+Vsig as the pixel voltage Vpix.

At a time t7, the controller 660 may provide the count enable signal CNT_EN having a logic high level to the reference signal generator 670, and the reference signal generator 670 may start to decrease the reference signal Vref at the same constant rate as at the time t3, e.g., a slope of ‘a’. The comparator may provide the comparison signal CMP having a logic high level to the counter since the pixel voltage Vpix is smaller than the reference signal Vref. The controller 660 may provide the count clock signal CLKC to the counter, and the counter may perform an up-counting from the first counting value, which corresponds to the reset component Vrst, in synchronization with the count clock signal CLKC.

At a time t8, the magnitude of the reference signal Vref may become smaller than the magnitude of the pixel voltage Vpix, and the comparator may provide the comparison signal CMP having a logic low level to the counter so that the counter stops performing the up-counting. At the time t8, the counter output of the counter may correspond to a difference between the first analog signal representing the reset component Vrst (e.g., −2 in the example of FIG. 11) and the second analog signal representing the detected incident light Vrst+Vsig (e.g., 17 in the example of FIG. 11). The difference may be an effective intensity of incident light Vsig (e.g., 15 in the example of FIG. 11). The counter may output the effective intensity of incident light Vsig as the digital signal.

At a time t9, the controller 660 may provide the count enable signal CNT_EN having a logic low level to the reference signal generator 670, and the reference signal generator 670 may stop generating the reference voltage Vref.

A period from the time t7 to the time t9 corresponds to a maximum time for detecting the detected incident light Vrst+Vsig. A length of the period from the time t7 to the time t9 may be determined as a certain number of the count clock signal CLKC according to a characteristic of the image sensor 700.

At a time t10, the row driver 630 may provide a deactivated row selection signal SEL (e.g., the row selection signal having a low level) to the selected row of the pixel array 620, and the counter may reset the counter output to zero.

After that, the image sensor 700 may repeat above described operations on each row to generate the digital signals row by row.

Example embodiments are not limited to the example configuration and operation described with reference to FIGS. 9, 10 and 11.

FIG. 12 is a diagram illustrating a stack structure of an image sensor according to some example embodiments.

Referring to FIG. 12, an image sensor according to some example embodiments may include a first layer 10, a second layer 20 and a third layer 30. Here, one layer may correspond to one semiconductor die.

The second layer 20 may be disposed above the first layer 10, and the third layer 30 may be disposed above the second layer 20, e.g., the second layer 20 may be disposed between the first layer 10 and the third layer 30. The first layer 10 may include a pixel array provided in a semiconductor substrate, and the second layer 20 and the third layer 30 may include logic circuitry.

The image sensor of FIG. 12 may be a three-stack image sensor including three layers 30, 40, and 50. Such a stacked structure may improve the integration of the image sensor. Furthermore, by placing the readout circuit etc. in a layer different from the pixel array, the design margin of the pixel array may be improved and the electrical characteristics of the pixel array may be improved.

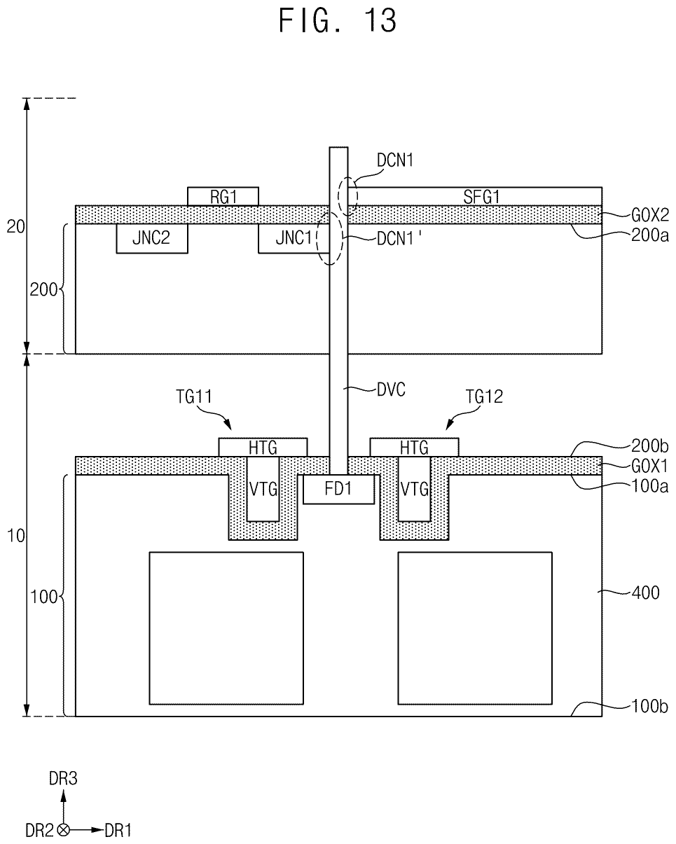

FIG. 13 is a cross-sectional view illustrating an example embodiment in which a direct contact is applied to a pixels included in an image sensor of a stack structure according to some example embodiments.

The direct contact according to some example embodiments may be efficiently applied to the stacked structure as illustrated in FIG. 12.

Referring to FIG. 13, a second semiconductor die 20 including a second semiconductor substrate 200 may be stacked above a first semiconductor die 10 including a first semiconductor substrate 100.

A first sub-pixel PX11, a second sub-pixel PX12, and a floating diffusion region FD1 may be disposed in the first semiconductor die 10, and a source follower gate SFG1 may be disposed above the second semiconductor die 20.

In some example embodiments, the direct contact DCN1 may include a vertical contact DVC extending in a vertical direction DR3 from the upper surface of the floating diffusion region FD1 of the first semiconductor die 10 to a metal layer of the second semiconductor die 20. A sidewall of the vertical contact DVC may be in contact with an end portion of the source follower gate SFG1 to implement the direct contact DCN1.

In some example embodiments, the reset transistor JNC1, JNC2 and RG1 may be disposed at the second semiconductor die 20. In this case, the sidewall of the vertical contact DVC may contact the junction region JNC1 of the reset transistor to implement an additional direct contact DCN1′.

Hereinafter, in FIGS. 14 through 18, components of a second pixel PX2, a third pixel PX3, and a fourth pixel PX4 are the same as the first pixel PX1 described with reference to FIGS. 1 through 5, except with different subscripts, and thus redundant descriptions are omitted. For example, the descriptions of the second floating diffusion region FD2 included in the second pixel PX2, the third floating diffusion region FD3 included in the third pixel PX3, and the fourth floating diffusion region FD4 included in the fourth pixel PX4 may be replaced by the description of the first floating diffusion region FD1 included in the first pixel PX1.

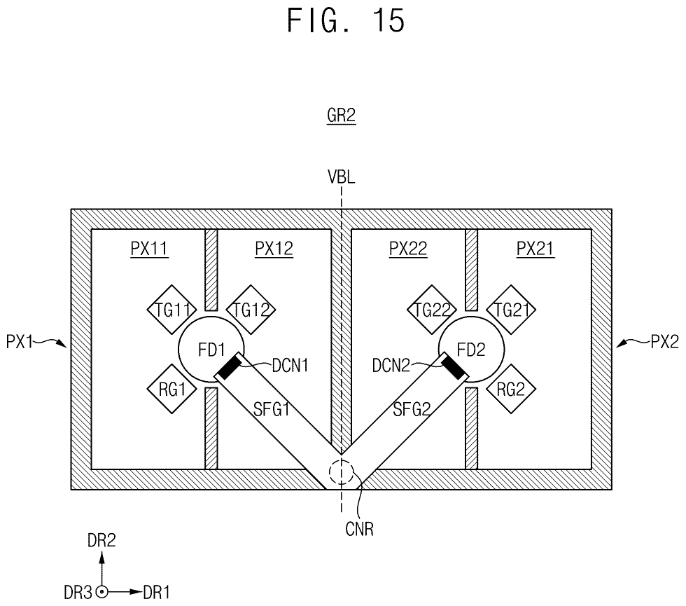

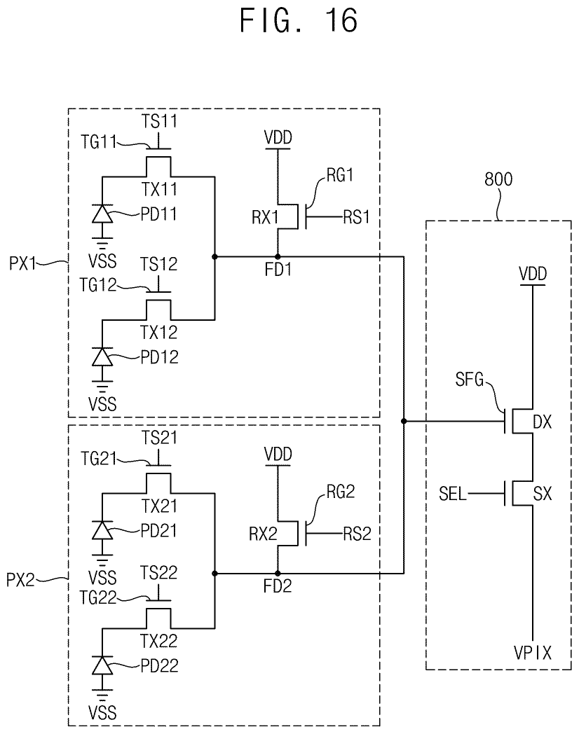

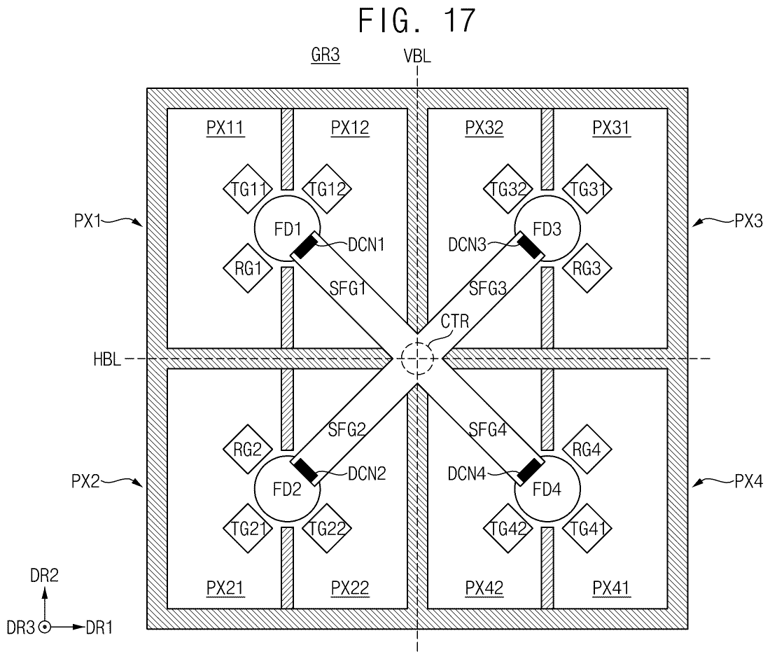

FIGS. 14 and 15 are plan views illustrating a layout of a pixel group included in an image sensor according to some example embodiments, and FIG. 16 is a circuit diagram illustrating a configuration corresponding to the pixel group of FIGS. 14 and 15 and a readout circuit.

Referring to FIGS. 14 and 16, a first pixel group GR1 includes a first pixel PX1 and a second pixel PX2 adjacent in a second horizontal direction DR2. The first pixel PX1 and the second pixel PX2 may be symmetrical with respect to a boundary line HBL parallel to the first horizontal direction DR1.

The first pixel PX1 may include a first floating diffusion region FD1, a first photodiode PD11 and a first transmission transistor TX11 in the first sub-pixel PX11, a second photodiode PD12 and a second transmission transistor TX12 in the second sub-pixel PX12, and a first reset transistor RX1. The first subpixel PX11, the second subpixel PX12, and the first reset transistor RX1 are connected in common to a first floating diffusion region FD1.

The first reset transistor RX1 of the first pixel PX1 is connected between a reset voltage such as a power supply voltage VDD and the first floating diffusion region FD1, and may be switched in response to a first reset signal RS1.

The second pixel PX2 may include a second floating diffusion region FD2, a first photodiode PD21 and a first transmission transistor TX21 in the first sub-pixel PX21, a second photodiode PD22 and a second transmission transistor TX22 in the second sub-pixel PX22, and a second reset transistor RX2. The first sub-pixel PX21, the second sub-pixel PX22, and the second reset transistor RX2 are connected in common to a second floating diffusion region FD2.

The second reset transistor RX2 of the second pixel PX2 is connected between the reset voltage VDD and the second floating diffusion region FD2, and may be switched in response to a second reset signal RS2.

The readout circuit 800, as described with reference to FIG. 6, may be shared by the first pixel PX1 and the second pixel PX2. In this case, a gate of the drive transistor DX, i.e., a source follower gate SFG, may be connected in common to the first floating diffusion region FD1 of the first pixel PX1 and the second floating diffusion region FD2 of the second pixel PX2, as shown in FIG. 16.

As shown in FIG. 14, each of the first source follower gate SFG1 of the first pixel PX1 and the second source follower gate SFG2 of the second pixel PX2 may extend to a corner region CNR on the boundary line HBL, and the first source follower gate SFG1 and the second source follower gate SFG2 may be connected to each other to form a single source follower gate SFG.

As described above, the first source follower gate SFG1 is connected to the first floating diffusion region FD1 via a first direct contact DCN1, and the second source follower gate SFG2 is connected to the second floating diffusion region FD2 via a second direct contact DCN2. As a result, one source follower gate SFG including the first source follower gate SFG1 and the second source follower gate SFG2 may be connected in common to the first floating diffusion region FD1 of the first pixel PX1 and the second floating diffusion region FD2 of the second pixel PX2.

Referring to FIGS. 15 and 16, a second pixel group GR2 may include a first pixel PX1 and a second pixel PX2 adjacent in the first horizontal direction DR1, and the first pixel PX1 and the second pixel PX2 may be symmetrical with respect to a vertical boundary line VBL parallel to the second horizontal direction DR2.

As shown in FIG. 15, each of the first source follower gate SFG1 of the first pixel PX1 and the second source follower gate SFG2 of the second pixel PX2 may extend to a corner region CNR on the boundary line VBL, and the first source follower gate SFG1 and the second source follower gate SFG2 may be connected to each other to form a single source follower gate SFG.

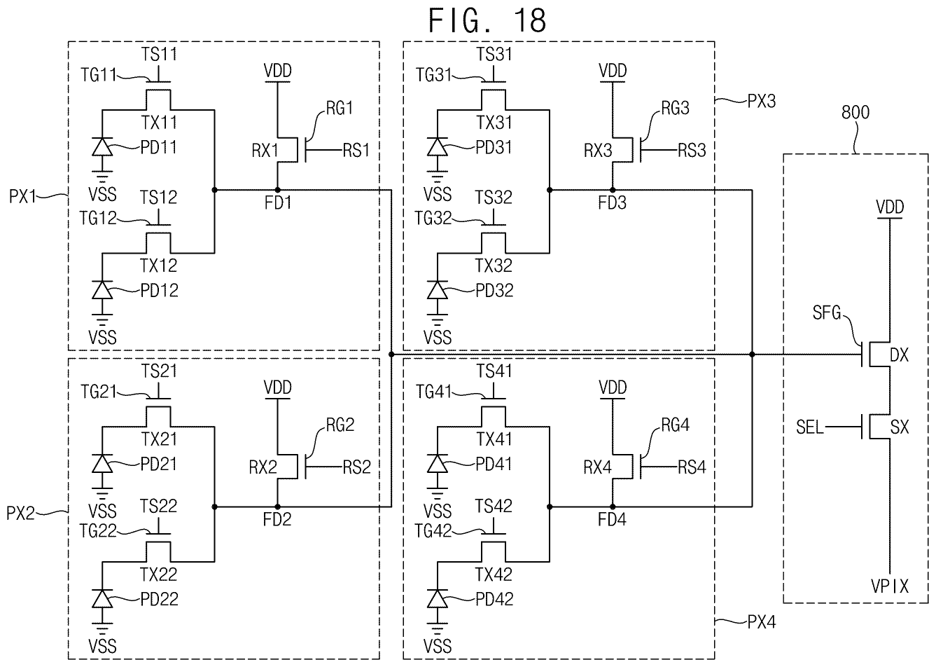

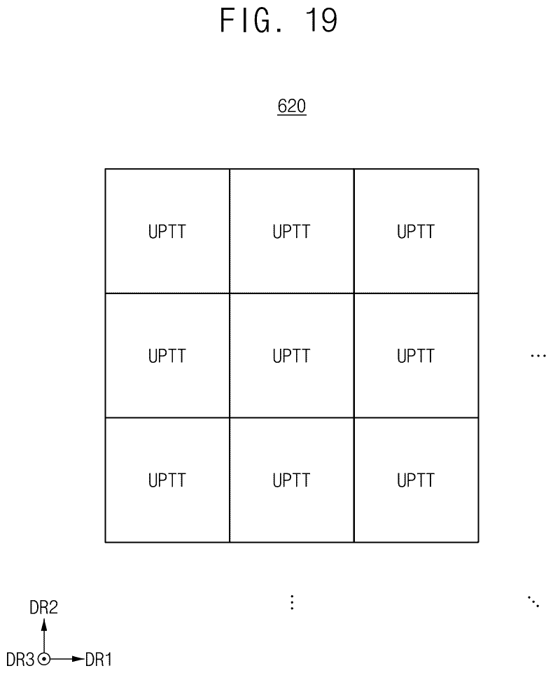

FIG. 17 is a plan view illustrating a layout of a pixel group included in an image sensor according to some example embodiments, and FIG. 18 is a circuit diagram illustrating a configuration corresponding to the pixel group of FIG. 17 and a readout circuit.

Referring to FIGS. 17 and 18, a third pixel group GR3 may include a first pixel PX1 and a second pixel PX2 adjacent in the second horizontal direction DR2, a third pixel PX3 adjacent in the first horizontal direction DR1 to the first pixel PX1, and a fourth pixel PX4 adjacent in the first horizontal direction DR1 to the second pixel PX2 and adjacent in the second horizontal direction DR2 to the third pixel PX3.

The first pixel PX1, the second pixel PX2, the third pixel PX3, and the fourth pixel PX4 may be symmetrical with respect to each of the first boundary line HBL parallel to the first horizontal direction DR1 and the second boundary line VBL parallel to the second horizontal direction DR2.

The first pixel PX1 may include a first floating diffusion region FD1, a first photodiode PD11 and a first transmission transistor TX11 in the first sub-pixel PX11, a second photodiode PD12 and a second transmission transistor TX12 in the second sub-pixel PX12, and a first reset transistor RX1. The first subpixel PX11, the second subpixel PX12, and the first reset transistor RX1 are connected in common to a first floating diffusion region FD1.

The first reset transistor RX1 of the first pixel PX1 is connected between a reset voltage, such as a power supply voltage VDD and the first floating diffusion region FD1, and may be switched in response to a first reset signal RS1.

The second pixel PX2 may include a second floating diffusion region FD2, a first photodiode PD21 and a first transmission transistor TX21 of the first sub-pixel PX21, a second photodiode PD22 and a second transmission transistor TX22 of the second sub-pixel PX22, and a second reset transistor RX2. The first sub-pixel PX21, the second sub-pixel PX22, and the second reset transistor RX2 are connected in common to a second floating diffusion region FD2.

The second reset transistor RX2 of the second pixel PX2 is connected between the reset voltage VDD, and the second floating diffusion region FD2 and may be switched in response to a second reset signal RS2.

The third pixel PX3 may include a third floating diffusion region FD3, a first photodiode PD31 and a first transmission transistor TX31 in the first sub-pixel PX31, a second photodiode PD32 and a second transmission transistor TX32 in the second sub-pixel PX32, and a third reset transistor RX3. The first subpixel PX31, the second subpixel PX32, and the third reset transistor RX3 are connected in common to a third floating diffusion region FD3.

A third reset transistor RX3 of the third pixel PX3 is connected between the reset voltage VDD, and the third floating diffusion region FD3 and may be switched in response to a third reset signal RS3.

The fourth pixel PX4 may include the fourth floating diffusion region FD4, a first photodiode PD41 and a first transmission transistor TX41 in the first sub-pixel PX41, a second photodiode PD42 and a second transmission transistor TX42 in the second sub-pixel PX42, and a fourth reset transistor RX4. The first subpixel PX41, the second subpixel PX42, and the fourth reset transistor RX4 are connected in common to a fourth floating diffusion region FD4.

The fourth reset transistor RX4 of the fourth pixel PX4 is connected between the reset voltage VDD, and the fourth floating diffusion region FD4 and may be switched in response to the fourth reset signal RS4.

The readout circuit 800, as described with reference to FIG. 6, may be shared by the first pixel PX1, the second pixel PX2, the third pixel PX3, and the fourth pixel PX4. In this case, as shown in FIG. 18, a gate of the drive transistor DX, i.e., a source follower gate SFG, may be connected in common to the first floating diffusion region FD1 of the first pixel PX1, the second floating diffusion region FD2 of the second pixel PX2, the third floating diffusion region FD3 of the third pixel PX3, and the fourth floating diffusion region FD4 of the fourth pixel PX.

As shown in FIG. 17, the first source follower gate SFG1 of the first pixel PX1, the second source follower gate SFG2 of the second pixel PX2, the third source follower gate SFG3 of the third pixel PX3, and the fourth source follower gate SFG4 of the fourth pixel PX4 may each extend to the group center region CTR where the first boundary line HBL and the second boundary line VBL intersect, The first source follower gate SFG1, the second source follower gate SFG2, the third source follower gate SFG3, and the fourth source follower gate SFG4 may be connected to each other to form a single source follower gate SFG.

As described above, the first source follower gate SFG1 is connected to the first floating diffusion region FD1 via a first direct contact DCN1, the second source follower gate SFG2 is connected to the second floating diffusion region FD2 via a second direct contact DCN2, the third source follower gate SFG3 is connected to the third floating diffusion region FD3 via a third direct contact DCN3, and the fourth source follower gate SFG4 is connected to the fourth floating diffusion region FD4 via a fourth direct contact DCN4. As a result, one source follower gate SFG integrally including the first source follower gate SFG1, the second source follower gate SFG2, the third source follower gate SFG3, and the fourth source follower gate SFG4 is connected in common to the first floating diffusion region FD1 of the first pixel PX1, the second floating diffusion region FD2 of the second pixel PX2, the third floating diffusion region FD3 of the third pixel PX3, and the fourth floating diffusion region FD4 of the fourth pixel PX.

FIG. 19 is a diagram illustrating a layout of a pixel array included in an image sensor according to some example embodiments.

Referring to FIG. 19, the pixel array 620 in the image sensor 600 of FIG. 6 may be divided into unit patterns UPTT that are arranged repeatedly in the first horizontal direction DR1 and the second horizontal direction DR2. Each unit pattern UPTT may include two or more pixel group where each pixel group includes one or more pixels as described above.

In some example embodiments, all of the unit patterns UPTT in the pixel array 620 may be identical. In some example embodiments, the unit pattern UPTT is a minimum pattern that cannot be divided into smaller patterns. In some example embodiments, the unit patterns UPTT in the pixel array 620 may include two or more different patterns such that the different patterns are arranged regularly in the first horizontal direction DR1 and/or the second horizontal direction DR2.

Referring now to FIGS. 20 through 24, example embodiments of unit patterns corresponding to various different pixel groups will be described. Depending on example embodiments, the pixel arrays described herein may be inverted in the first horizontal direction DR1 and/or the second horizontal direction DR2 and/or rotated about a vertical direction DR3 by 90 degrees or 180 degrees.

FIGS. 20 through 24 are plan views illustrating example embodiments of an arrangement pattern of a pixel array included in an image sensor according to some example embodiments.

Referring to FIG. 20, the pixel PX1 of FIG. 1 corresponds to the unit pattern UPTT and a pixel array PARR1 may include pixels PX1 repeatedly arranged in the first horizontal direction DR1 and the second horizontal direction DR2.

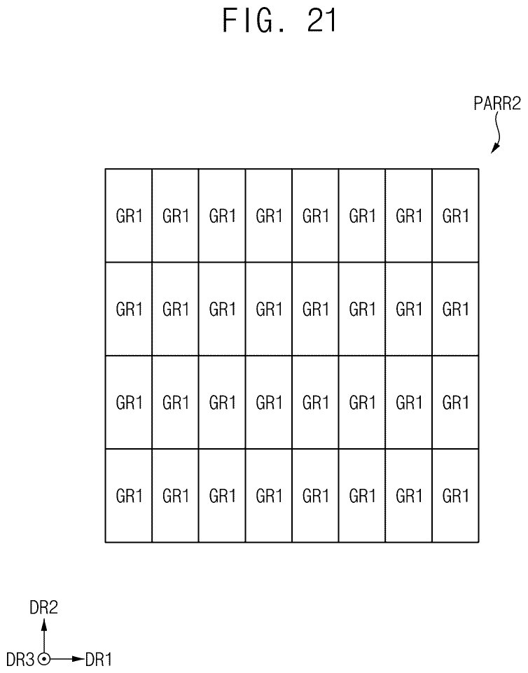

Referring to FIG. 21, the first pixel group GR1 of FIG. 14 corresponds to the unit pattern UPTT and a pixel array PARR2 may include the first pixel groups GR1 repeatedly arranged in the first horizontal direction DR1 and the second horizontal direction DR2.

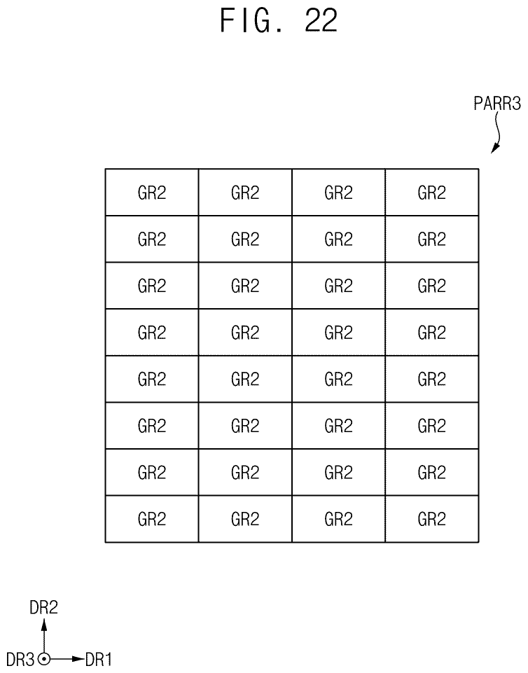

Referring to FIG. 22, the second pixel groups GR2 of FIG. 15 may correspond to the unit pattern UPTT, and a pixel array PARR3 may include the second pixel groups GR2 repeatedly arranged in the first horizontal direction DR1 and the second horizontal direction DR2.

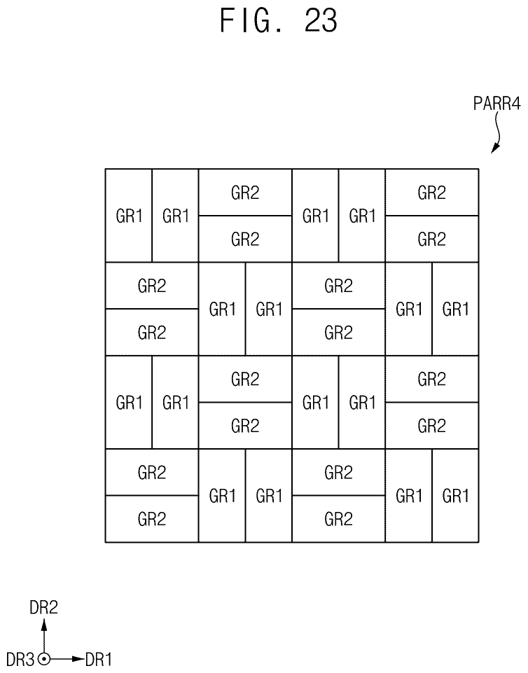

Referring to FIG. 23, the first pixel group GR1 of FIG. 14 and the second pixel group GR2 of FIG. 15 may be paired by two, and a pixel array PARR4 may include two first pixel groups GR1 and two second pixel groups GR2 repeatedly arranged alternately in the first horizontal direction DR1 and the second horizontal direction DR2. In this case, a set of the four first pixel groups GR1 and the four second pixel groups GR2 forming a square shape corresponds to a unit pattern UPTT.

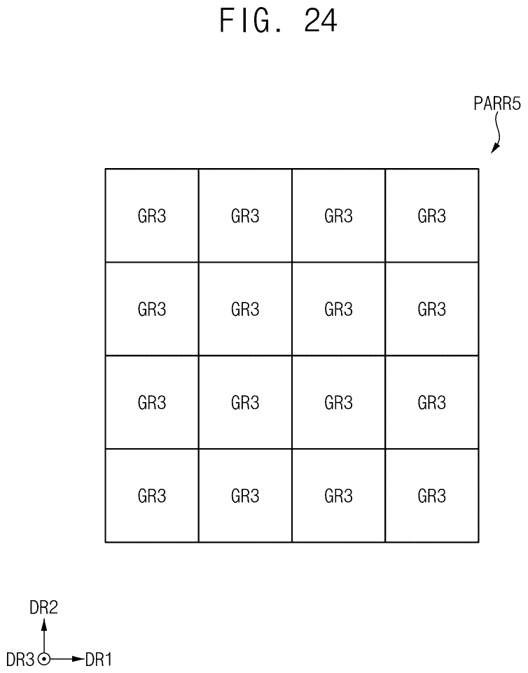

Referring to FIG. 24, the third pixel group GR3 of FIG. 17 corresponds to the unit pattern UPTT, and a pixel array PARR5 may include the third pixel groups GR3 repeatedly arranged in the first horizontal direction DR1 and the second horizontal direction DR2.

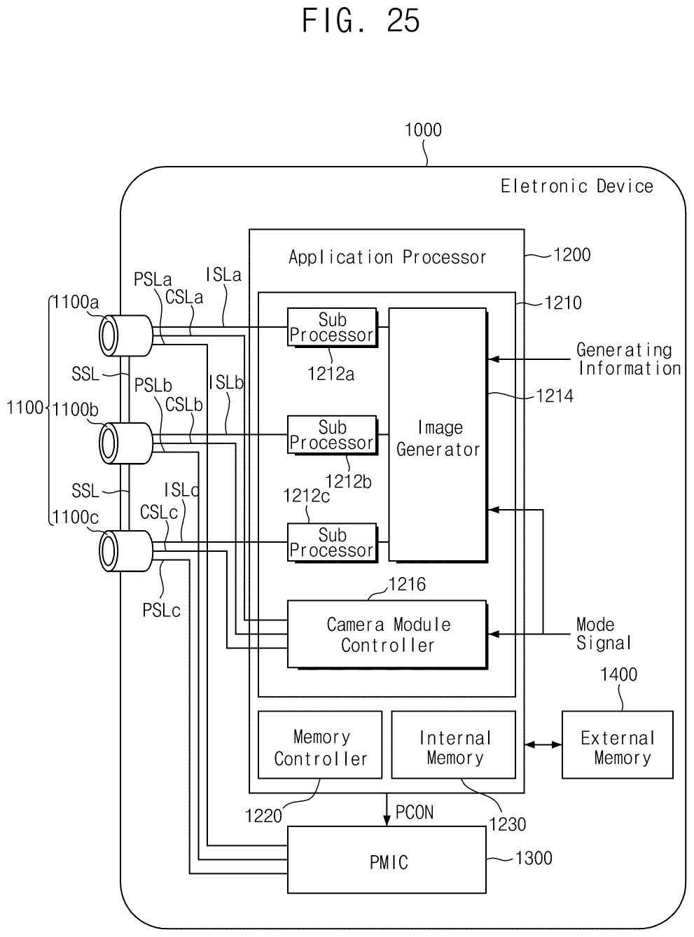

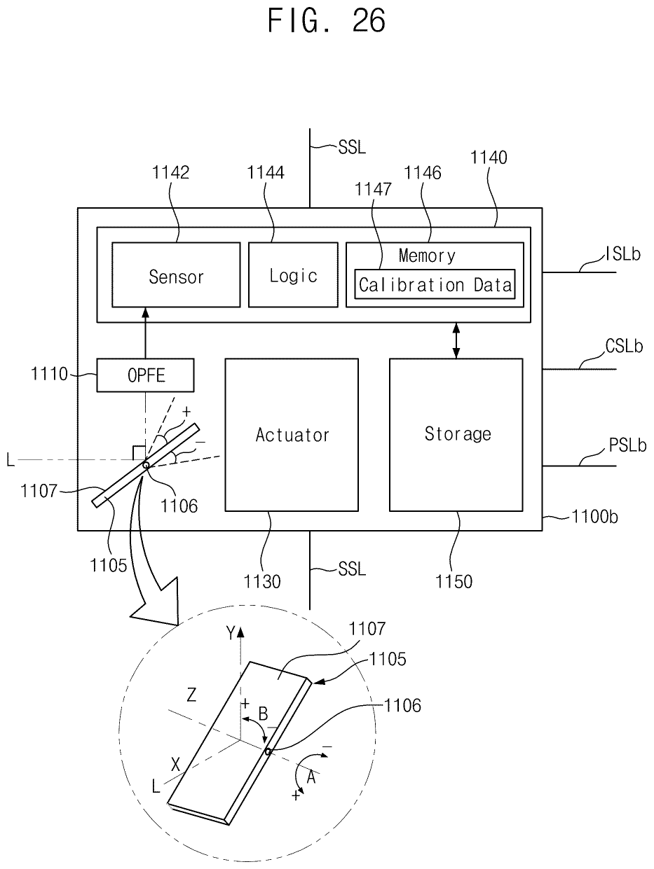

FIG. 25 is a block diagram illustrating an electronic device according to some example embodiments, and FIG. 26 is a block diagram illustrating a camera module included in the electronic device of FIG. 25.

Referring to FIG. 25, an electronic device 1000 may include a camera module group 1100, and application processor 1200, a power management integrated circuit (PMIC) 1300 and/or an external memory 1400.

The camera module group 1100 may include a plurality of camera modules 1100a, 1100b and 1100c. FIG. 25 illustrates the three camera modules 1100a, 1100b and 1100c as an example, but example embodiments are not limited to a particular number of camera modules. According to some example embodiments, the camera module group 1100 may include two camera modules, and four or more camera modules.

Hereinafter, an example configuration of the camera module 1100b is described with reference to FIG. 26. According to some example embodiments, the same descriptions may be applied to the other camera modules 1100a and 1100c.

Referring to FIG. 26, the camera module 1100b may include a prism 1105, an optical path folding element (OPFE) 1110, an actuator 1130, an image sensing device 1140 and a storage device 1150.

The prism 1105 may include a reflection surface 1107 to change a path of a light L incident on the prism 1105.

In some example embodiments, the prism 1105 may change the path of the light L incident in a first direction X to the path in a second direction Y perpendicular to the first direction X. In addition, the prism 1105 may rotate the reflection surface 1107 around a center axis 1106 and/or rotate the center axis 1106 in the B direction to align the path of the reflected light along the second direction Y. In addition, the OPFE 1110 may move in a third direction perpendicular to the first direction X and the second direction Y.

In some example embodiments, a rotation angle of the prism 1105 may be smaller than 15 degrees in the positive (+) A direction and greater than 15 degrees in the negative (−) A direction, but example embodiments are not limited thereto.

In some example embodiments, the prism 1105 may rotate within 20 degrees in the positive B direction and the negative B direction.

In some example embodiments, the prism 1105 may move the reflection surface 1106 in the third direction Z that is in parallel with the center axis 1106.

The OPFE 1110 may include optical lenses that are divided into m groups where m is a positive integer. The m lens group may move in the second direction Y to change an optical zoom ratio of the camera module 1100b. For example, the optical zoom ratio may be changed in a range of 3K, 5K, and so on by moving the m lens group, when K is a basic optical zoom ratio of the camera module 1100b.

The actuator 1130 may move the OPFE 1110 or the optical lens to a specific position. For example, the actuator 1130 may adjust the position of the optical lens for accurate sensing such that an image sensor 1142 may be located at a position corresponding to a focal length of the optical lens.

The image sensing device 1140 may include the image sensor 1142, a control logic 1144 and/or a memory 1146. The image sensor 1142 may capture or sense an image using the light provided through the optical lens. The control logic 1144 may control overall operations of the camera module 1100b. For example, the control logic 1144 may provide control signals through control signal line CSLb to control the operation of the camera module 1100b.

The memory 1146 may store information such as calibration data 1147 for the operation of the camera module 1100b. For example, the calibration data 1147 may include information for generation of image data based on the provided light, such as information on the above-described rotation angle, a focal length, information on an optical axis, and so on. When the camera module 1100b is implemented as a multi-state camera having a variable focal length depending on the position of the optical lens, the calibration data 1147 may include multiple focal length values and auto-focusing values corresponding to the multiple states.

The storage device 1150 may store the image data sensed using the image sensor 1142. The storage device 1150 may be disposed outside of the image sensing device 1140, and the storage device 1150 may be stacked with a sensor chip comprising the image sensing device 1140. The storage device 1150 may be implemented with an electrically erasable programmable read-only memory (EEPROM), but example embodiments are not limited thereto.

Referring to FIGS. 25 and 26, each of the camera modules 1100a, 1100b and 1100c may include the actuator 1130. In some example embodiments, the camera modules 1100a, 1100b and 1100c may include the same or different calibration data 1147 depending on the operations of the actuators 1130.

In some example embodiments, one camera module 1100b may have a folded lens structure included the above-described prism 1105 and the OPFE 1110, and the other camera modules 1100a and 1100b may have a vertical structure without the prism 1105 and the OPFE 1110.

In some example embodiments, one camera module 1100c may be a depth camera configured to measure distance information of an object using an infrared light. In some example embodiments, the application processor 1200 may merge the distance information provided from the depth camera 1100c and image data provided from the other camera modules 1100a and 1100b to generate a three-dimensional depth image.

In some example embodiments, at least two camera modules among the camera modules 1100a, 1100b and 1100c may have different field of views, for example, through different optical lenses.

In some example embodiments, each of the camera modules 1100a, 1100b and 1100c may be separated physically from each other. In other words, the camera modules 1100a, 1100b and 1100c may each include a dedicated image sensor 1142.

The application processor 1200 may include an image processing device 1210, a memory controller 1220 and an internal memory 1230. The application processor 1200 may be separated from the camera modules 1100a, 1100b and 1100c. For example, the application processor 1200 may be implemented as one chip and the camera modules 1100a, 1100b and 1100c may implemented as another chip or other chips.

The image processing device 1210 may include a plurality of sub processors 1212a, 1212b and 1212c, an image generator 1214 and a camera module controller 1216.

The image data generated by the camera modules 1100a, 1100b and 1100c may be provided to the sub processors 1212a, 1212b and 1212c through distinct image signal lines ISLa, ISLb and ISLc, respectively. For example, the transfer of the image data may be performed using a camera serial interface (CSI) based on the mobile industry processor interface (MIPI), but example embodiments are not limited thereto.

In some example embodiments, one sub processor may be assigned commonly to two or more camera modules. In some example embodiments, a multiplexer may be used to transfer the image data selectively from one of the camera modules to the shared sub processor.

The image data from the sub processors 1212a, 1212b and 1212c may be provided to the image generator 1214. The image generator 1214 may generate an output image using the image data from the sub processors 1212a, 1212b and 1212c according to image generating information or a mode signal. For example, the image generator 1213 may merge at least a portion of the image data from the camera modules 1100a, 1100b and 1100c having the different fields of view to generate the output image according to the image generating information or the mode signal. In addition, the image generator 1214 may select, as the output image, one of the image data from the camera modules 1100a, 1100b and 1100c according to the image generating information or the mode signal.

In some example embodiments, the image generating information may include a zoom factor or a zoom signal. In some example embodiments, the mode signal may be a signal based on a selection of a user.

When the image generating information is the zoom factor and the camera modules 1100a, 1100b and 1100c have the different field of views, the image generator 1214 may perform different operation depending on the zoom signal. For example, when the zoom signal is a first signal, the image generator 1214 may merge the image data from the different camera modules to generate the output image. When the zoom signal is a second signal different from the first signal, the image generator 1214 may select, as the output image, one of image data from the camera modules 1100a, 1100b and 1100c.

In some example embodiments, the image generator 1214 may receive the image data of different exposure times from the camera modules 1100a, 1100b and 1100c. In some example embodiments, the image generator 1214 may perform high dynamic range (HDR) processing with respect to the image data from the camera modules 1100a, 1100b and 1100c to generate the output image having the increased dynamic range.

The camera module controller 1216 may provide control signals to the camera modules 1100a, 1100b and 1100c. The control signals generated by the camera module controller 1216 may be provided to the camera modules 1100a, 1100b and 1100c through the distinct control signal lines CSLa, CSLb and CSLc, respectively.

In some example embodiments, one of the camera modules 1100a, 1100b and 1100c may be designated as a master camera according to the image generating information of the mode signal, and the other camera modules may be designated as slave cameras.

The camera module acting as the master camera may be changed according to the zoom factor or an operation mode signal. For example, when the camera module 1100a has the wider field of view than the camera module 1100b and the zoom factor indicates a lower zoom magnification, the camera module 1100b may be designated as the master camera. In contrast, when the zoom factor indicates a higher zoom magnification, the camera module 1100a may be designated as the master camera.

In some example embodiments, the control signals provided from the camera module controller 1216 may include a synch enable signal. For example, when the camera module 1100b is the master camera and the camera modules 1100a and 1100c are the slave cameras, the camera module controller 1216 may provide the synch enable signal to the camera module 1100b. The camera module 1100b may generate a synch signal based on the provided synch enable signal and provide the synch signal to the camera modules 1100a and 1100c through a synch signal line SSL. As such, the camera modules 1100a, 1100b and 1100c may transfer the synchronized image data to the application processor 1200 based on the synch signal.

In some example embodiments, the control signals provided from the camera module controller 1216 may include information on the operation mode. The camera modules 1100a, 1100b and 1100c may operate in a first operation mode or a second operation mode based on the information from the camera module controller 1216.

In the first operation mode, the camera modules 1100a, 1100b and 1100c may generate image signals with a first speed (e.g., a first frame rate) and encode the image signals with a second speed higher than the first speed (e.g., a second frame rate higher than the first frame rate) to transfer the encoded image signals to the application processor 1200. The second speed may be lower than thirty times the first speed. The application processor 1200 may store the encoded image signals in the internal memory 1230 or the external memory 1400. The application processor 1200 may read out and decode the encoded image signals to provide display data to a display device. For example, the sub processors 1212a, 1212b and 1212c may perform the decoding operation and the image generator 1214 may process the decoded image signals.

In the second operation mode, the camera modules 1100a, 1100b and 1100c may generate image signals with a third speed lower than the first speed (e.g., the third frame rate lower than the first frame rate) to transfer the generated image signals to the application processor 1200. In other words, the image signals that are not encoded may be provided to the application processor 1200. The application processor 1200 may process the received image signals or store the receive image signals in the internal memory 1230 or the external memory 1400.

The PMIC 1300 may provide a power supply voltage to the camera modules 1100a, 1100b and 1100c, respectively. For example, the PMIC 1300 may provide, under control of the application processor 1200, a first power to the camera module 1100a through a power line PSLa, a second power to the camera module 1100b through a power line PSLb, and a third power to the camera module 1100c through a power line PSLc.

The PMIC 1300 may generate the power respectively corresponding to the camera modules 1100a, 1100b and 1100c and control power levels, in response to a power control signal PCON from the application processor 1200. The power control signal PCON may include information on the power depending on the operation modes of the camera modules 1100a, 1100b and 1100c. For example, the operation modes may include a low power mode in which the camera modules 1100a, 1100b and 1100c operate in low powers. The power levels of the camera modules 1100a, 1100b and 1100c may be the same as or different from each other. In addition, the power levels may be changed dynamically or adaptively.

As described above, pixel and the image sensor according to some example embodiments may reduce the capacitance of the floating diffusion region and the source follower gate and increase the conversion gain of the pixel, by connecting the floating diffusion region and the source follower gate using the direct contact.

Alternatively or additionally, the pixel and the image sensor according to some example embodiments may reduce the amount of metal consumed in the manufacturing process to reduce manufacturing costs by replacing the metal lines above the pixel with the direct contact, and improve the electrical characteristics of the pixel and the image sensor by reducing interference between metal lines.

Example embodiments may be applied to any electronic devices and systems including an image sensor. For example, the embodiments may be applied to systems such as one or more of a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, an augmented reality (AR) device, a vehicle navigation device, a video phone, a monitoring system, an auto focusing system, a tracking system, a motion detection system, etc.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

The foregoing is illustrative of some example embodiments and is not to be construed as limiting thereof. Although a few example embodiments have been described, those skilled in the art will readily appreciate that many modifications are possible in the example embodiments without materially departing from the example embodiments. Further, example embodiments are not necessarily mutually exclusive with one another. For example, some example embodiments may include one or more features described with reference to one or more figures, and may also include one or more other features described with reference to one or more other figures.

What is claimed is:

1. A pixel of an image sensor, comprising:
a first sub-pixel including a first photoelectric conversion element in a semiconductor substrate;
a second sub-pixel including a second photoelectric conversion element in the semiconductor substrate;
a floating diffusion region in the semiconductor substrate and shared by the first sub-pixel and the second sub-pixel;
a gate insulating layer above the semiconductor substrate;
a source follower gate above the gate insulating layer;
a contact connecting the floating diffusion region and the source follower gate not via a metal line in a metal layer.

2. The pixel of claim 1, wherein the gate insulating layer does not include a portion above the floating diffusion region, and the contact includes a conductive material filling the portion to connect the floating diffusion region and the source follower gate.

3. The pixel of claim 2, wherein the conductive material of the contact is same as a conductive material of the source follower gate.

4. The pixel of claim 2, wherein the conductive material of the contact includes polysilicon.

5. The pixel of claim 2, wherein the conductive material of the contact includes barrier metal.

6. The pixel of claim 1, wherein the gate insulating layer does not include a portion above the floating diffusion region, and the source follower gate includes the portion of the gate insulating layer corresponding to the contact.

7. The pixel of claim 1, wherein the contact includes a vertical contact extending in a vertical direction from an upper surface of the floating diffusion region and an end portion of the source follower gate contacts a sidewall of the vertical contact.

8. The pixel of claim 1, wherein the source follower gate vertically overlaps an end portion of the floating diffusion region, the gate insulating layer has a cut-out portion, the cut-out portion corresponding to a vertically overlapping portion of the floating diffusion region and the source follower gate, and a vertical contact corresponds to the contact in the vertically overlapping portion.

9. The pixel of claim 1, wherein the first sub-pixel and the second sub-pixel share one microlens, and the pixel includes a two photodiode pixel configured to autofocus.

10. The pixel of claim 1, wherein the source follower gate extends from the floating diffusion region to a corner region of the pixel having a rectangular shape.

11. The pixel of claim 1, wherein
an inter-pixel trench structure isolates the pixel and neighboring pixels;
an intra-pixel trench structure isolates the first sub-pixel and the second sub-pixel; and
a central portion of the intra-pixel trench structure is only partially removed from an upper surface of the semiconductor substrate, and the floating diffusion region is in the central portion from which the intra-pixel trench structure is removed.

12. An image sensor comprising:
a pixel array including a plurality of pixels configured to collect photo charges generated by an incident light;
a row driver configured to drive the pixel array row by row; and
a controller configured to control the pixel array and the row driver,
each pixel of the plurality of pixels comprising,
a first sub-pixel including a first photoelectric conversion element in a semiconductor substrate,
a second sub-pixel including a second photoelectric conversion element in the semiconductor substrate;
a floating diffusion region in the semiconductor substrate and shared by the first sub-pixel and the second sub-pixel;
a gate insulating layer above the semiconductor substrate;
a source follower gate above the gate insulating layer; and
a contact connecting the floating diffusion region and the source follower gate not via a metal line in a metal layer.

13. The image sensor of claim 12, wherein
the pixel array includes pixel groups arranged repeatedly in a first horizontal direction and a second horizontal direction perpendicular to each other,
each pixel group includes a first pixel and a second pixel adjacent to each other in the second horizontal direction, and
the first pixel and the second pixel are symmetrical with respect to a boundary line parallel to the first horizontal direction.

14. The image sensor of claim 13, wherein each of a first source follower gate of the first sub-pixel and a second source follower gate of the second sub-pixel extends to a corner region on the boundary line, and the first source follower gate and the second source follower gate are connected to each other to form a single source follower gate.

15. The image sensor of claim 12, wherein
the pixel array includes pixel groups arranged repeatedly in a first horizontal direction and a second horizontal direction perpendicular to each other,
each pixel group includes a first pixel and a second pixel adjacent to each other in the second horizontal direction, a third pixel adjacent to the first pixel in the first horizontal direction, and a fourth pixel adjacent to the second pixel in the first horizontal direction and adjacent to the third pixel in the second horizontal direction, and
the first pixel, the second pixel, the third pixel and the fourth pixel are symmetrical with respect to a first boundary line parallel to the first horizontal direction and with respect to a second boundary line parallel to the second horizontal direction.

16. The image sensor of claim 15, wherein each of a first source follower gate of the first sub-pixel, a second source follower gate of the second sub-pixel, a third source follower gate of a third sub-pixel, a fourth source follower gate of a fourth sub-pixel extends to a central region on where the first boundary line and the second boundary line intersect, and the first source follower gate, the second source follower gate, the third source follower gate and the fourth source follower gate are connected to each other to form a single source follower gate.

17. The image sensor of claim 12, wherein
the image sensor has a structure in which a second semiconductor die is stacked above a first semiconductor die,
the first sub-pixel, the second sub-pixel and the floating diffusion region are in the first semiconductor die,
the source follower gate is above the second semiconductor die, and
the contact includes a vertical contact extending in a vertical direction from an upper surface of the floating diffusion region, and an end portion of the source follower gate contacts a sidewall of the vertical contact.

18. The image sensor of claim 17, further comprising:
a reset transistor at the second semiconductor die,
wherein a sidewall of the vertical contact contacts a junction region of the reset transistor.

19. A pixel of an image sensor, comprising:
a first sub-pixel;
a second sub-pixel;
a microlens shared by the first sub-pixel and the second sub-pixel;
a floating diffusion region in a semiconductor substrate and shared by the first sub-pixel and the second sub-pixel;
a gate insulating layer above the semiconductor substrate;
a source follower gate above the gate insulating layer; and
a direct contact connecting the floating diffusion region and the source follower gate not via a metal line in a metal layer.

20. The pixel of claim 19, wherein the gate insulating layer does not include a portion above the floating diffusion region, and the contact includes a conductive material filling the portion to connect the floating diffusion region and the source follower gate.
